(19) United States
(12) Patent Application Publication
(10) Pub. No.: US 2009/0047114 A1
(43) Pub. Date: Feb. 19, 2009

(54) APPARATUS FOR MANUFACTURING THIN-FILM LAMINATED MEMBER AND METHOD OF CONVEYING THE MEMBER THEREIN

(75) Inventors: Shoji YOKOYAMA, Tokyo (JP); Takashi OUCHI, Ichihara-shi (JP); Mitsuhiro NARUSE, Tokyo (JP); Takashi KAMOSHIDA, Yamato-shi (JP)

Correspondence Address: ROSSI, KIMMS & McDOWELL LLP., 20609 Gordon Park Square, Suite 150, Ashburn, VA, 20147, US

(73) Assignee: FUJI ELECTRIC HOLDINGS CO., LTD., Kawasaki-ku (JP)

(21) Appl. No.: 12/185,212

(22) Filed: Aug. 4, 2008

(30) Foreign Application Priority Data
Aug. 3, 2007 (JP) 2007-202694
Aug. 3, 2007 (JP) 2007-202695
Aug. 3, 2007 (JP) 2007-202696

(51) Int. Cl. H01L 21/677; B32B 37/02

(52) U.S. Cl. 414/806; 156/576

(57) ABSTRACT

An apparatus for manufacturing a thin-film laminated member by laminating a plurality of thin films on the surface of a band-shaped flexible substrate includes a substrate conveying device for conveying the band-shaped flexible substrate in the horizontal direction with the widthwise direction of the band-shaped flexible substrate oriented in the vertical direction. A plurality of film forming chambers are arranged in succession along the direction in which the band-shaped flexible substrate is conveyed for forming films on the surface of the band-shaped flexible substrate. A pair of upper grip rollers are arranged between the plurality of film forming chambers for pinching an upper edge portion of the band-shaped flexible substrate while the band-shaped flexible substrate is being conveyed. A method thereof includes pinching the upper edge portion of the band-shaped flexible substrate with the pairs of upper grip rollers.

### BACKGROUND

In general, a high-rigidity substrate is used as a substrate for a thin-film laminated member, such as a semiconductor thin-film. A flexible substrate formed of resin or the like, however, also can be used as a substrate for a photoelectric conversion element, for example, for a solar battery or the like because of its desirable property, namely light-weight, easy-to-handle, and for cost reduction by mass-production.

In an apparatus for manufacturing a thin-film laminated member using the flexible substrate, a band-shaped flexible substrate is passed through a plurality of film-forming chambers arranged in succession to repeat a film forming operation on the flexible substrate while in a halted state in each film forming chamber. Thereafter, the flexible substrate is transferred to a position of the next film forming chamber to laminate a plurality of thin films having different characteristics on the flexible substrate. See for example JP-A-2005-72408.

The film forming apparatus described above includes a type that holds the band-shaped flexible substrate oriented horizontally and forms the films while conveying the band-shaped flexible substrate in the horizontal direction, i.e., in a state where the surface of the band-shaped flexible substrate to be formed with the films is oriented in the horizontal direction. It also includes a type that holds the band-shaped flexible substrate oriented vertically along the widthwise direction and forms the films while conveying the band-shaped flexible substrate in the horizontal direction, i.e., in a state where the surface of the band-shaped flexible substrate to be formed with the films is oriented vertically. The latter type has an advantage in that the surface of the substrate is hardly contaminated in comparison with the former type. When the number of film forming chambers increases, the surface of the band-shaped flexible substrate becomes wrinkled due to the gravitational force or elongation of the band-shaped flexible substrate, the band-shaped flexible substrate snakes along the widthwise direction (i.e., meanders), or the band-shaped flexible substrate sags.

To solve the above problems, a proposal has been made to arrange an intermediate chamber between two film-forming chambers positioned in the middle of a number of film-forming chambers and provide an edge position controlling (EPC) roller that comes into contact with the surface of the substrate over the entire surface of the substrate along the widthwise direction in the intermediate chamber. In general, however, since the film-formation is carried out at a relatively high temperature, when the EPC roller formed of stainless-steel is arranged between the film-forming chambers, the substrate rapidly cools down, creating wrinkles.

Accordingly, there still remains a need for a way of preventing wrinkles on the surface, widthwise meandering, and sagging of the band-shaped flexible substrate even when the band-shaped flexible substrate is conveyed in the horizontal direction for a long distance while oriented vertically in the widthwise direction to maintain the position of the band-shaped flexible substrate in the vertical direction at a high degree of accuracy. The present invention addresses this need.

### SUMMARY OF THE INVENTION

The present invention relates to an apparatus for manufacturing a thin-film laminated member, such as a thin-film photoelectric conversion element, by forming a plurality of thin-films on a band-shaped flexible substrate, and a method of conveying the band-shaped flexible substrate in the apparatus.

One aspect of the present invention is an apparatus for manufacturing a thin-film laminated member by laminating a plurality of thin films on the surface of a band-shaped flexible substrate. The apparatus can include a substrate conveying device for conveying the band-shaped flexible substrate horizontally with the band-shaped flexible substrate oriented vertically in the widthwise direction, a plurality of film forming chambers arranged in succession along the direction in which the band-shaped flexible substrate is conveyed for forming films on the surface of the band-shaped flexible substrate, and at least a pair of upper grip rollers arranged between the plurality of film forming chambers and configured to pinch an upper edge portion of the band-shaped flexible substrate while the band-shaped flexible substrate is being conveyed.

A plurality of pairs of the upper grip rollers can be arranged adjacent at least one of the film forming chambers for pinching the upper edge portion of the band-shaped flexible substrate. Moreover, the direction of rotation of the pairs of upper grip rollers can be inclined obliquely upwardly with respect to the direction in which the band-shaped flexible substrate is conveyed.

At least one pair of lower grip rollers for pinching the lower edge portion of the band-shaped flexible substrate can be provided between the film forming chambers. Moreover, the direction of rotation of the pairs of lower grip rollers can be inclined obliquely downwardly with respect to the direction in which the band-shaped flexible substrate is conveyed.

Another aspect of the present invention is a method of conveying the band-shaped flexible substrate in an apparatus for manufacturing a thin-film laminated member by laminating a plurality of thin films on the surface of the band-shaped flexible substrate in the plurality of film forming chambers arranged in succession along the direction in which the band-shaped flexible substrate is conveyed. The method includes the steps of conveying the band-shaped flexible substrate horizontally with the band-shaped flexible substrate oriented vertically in the widthwise direction and pinching an upper edge portion of the band-shaped flexible substrate with at least a pair of upper grip rollers arranged between the plurality of film forming chambers while the band-shaped flexible substrate is being conveyed.

The method can further include the step of pinching the lower edge portion of the band-shaped flexible substrate with at least one pair of lower grip rollers provided between the film forming chambers while the band-shaped flexible substrate is being conveyed.

### BRIEF DESCRIPTION OF THE DRAWINGS

FIG. 1 schematically illustrates a plan view an apparatus for manufacturing a thin-film laminated member according to the present invention.

FIG. 2 illustrates a front view viewed taken along the line II-II of FIG. 1.

FIG. 3A schematically illustrates an enlarged plan cross-section of the film forming chamber shown in FIG. 1.

FIG. 3B is a front view taken along the line IIIB-IIIB of FIG. 3A.

FIG. 4 schematically illustrates a perspective view of grip rollers and the attached device thereof.

FIG. 5 is a front view of the grip rollers of FIG. 4 and the attached device thereof.

FIG. 6 schematically illustrates a plan view of an experimental device used in testing in Example 2.

FIG. 7 schematically illustrates a plan view of another experimental device used in testing in Example 2.

FIG. 8 is a graph showing a result of a test in which a Kapton film is used in the experimental device of FIG. 6.

FIG. 9 is a graph showing a result of a test in which the Kapton film is used in the experimental device of FIG. 7.

FIG. 10 is a graph showing a result of a test in which an amorphous silicon film is used in the experimental device of FIG. 6.

FIG. 11 is a graph showing a result of a test in which the amorphous silicon film is used in the experimental device of FIG. 7.

### DETAILED DESCRIPTION

Although the detailed configuration of the thin-film laminated member is not specifically described here, the present apparatus and method can be adapted to manufacture of the thin-film laminated member such as a photoelectric conversion element for a solar battery or a semiconductor thin film such as an organic EL or the like.

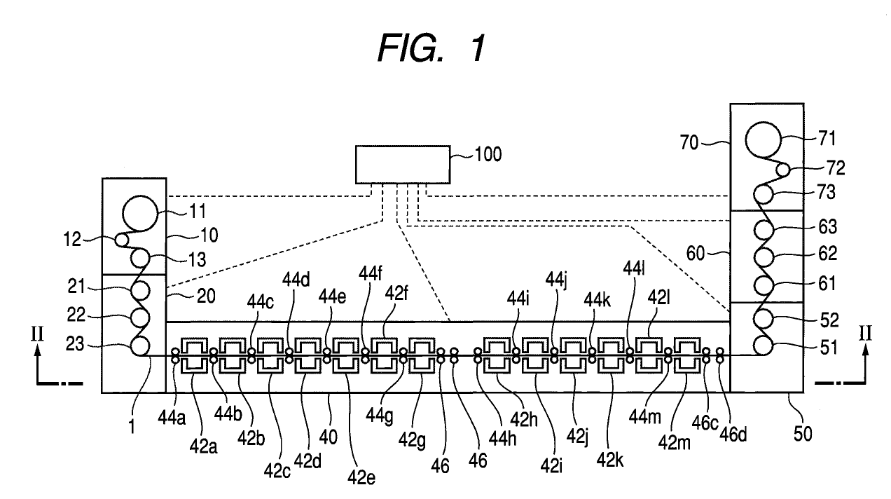

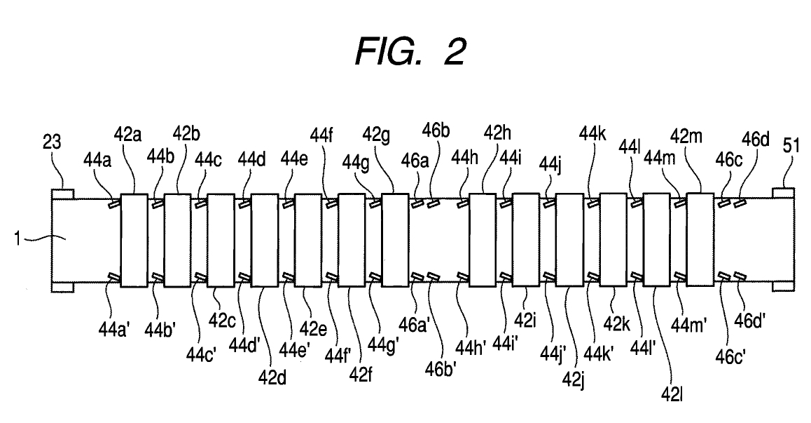

Referring to FIGS. 1 and 2, the present apparatus for manufacturing a thin-film laminated member can include an unwinding unit 10 for feeding a band-shaped flexible substrate 1, an unwinding drive 20 for conveying the band-shaped flexible substrate 1 from the unwinding unit 10 to a film forming section 40, the film forming section 40 for laminating a plurality of thin films on the band-shaped flexible substrate 1, a side edge position controller 50 for controlling the edge position of the band-shaped flexible substrate 1, a winding side drive 60 for conveying the band-shaped flexible substrate 1 from the film forming section 40 to a winding unit 70, and the winding unit 70 for winding the band-shaped flexible substrate 1 formed with the thin-film laminated member. The band-shaped flexible substrate 1 is conveyed in the horizontal direction while the substrate is oriented vertically along the widthwise direction.

The unwinding unit 10 includes an unwinding core 11 that rotatably supports a whole roll of the band-shaped flexible substrate 1 and feeds the band-shaped flexible substrate 1, a tensile strength detection roller 13 for detecting the tensile strength of the band-shaped flexible substrate 1 fed from the unwinding core 11, and an auxiliary roller 12. The unwinding core 11, the auxiliary roller 12, and the tensile strength detection roller 13 are arranged with their axial directions thereof all oriented vertically. The respective rollers described below are also arranged with their axial direction oriented vertically.

The unwinding drive 20 is provided with an unwinding-side film drive roller 21 that rotates for conveying the band-shaped flexible substrate 1 from the unwinding unit 10 to the film forming section 40, a tensile strength detection roller 22 for detecting the tensile strength of the band-shaped flexible substrate 1 when being driven, and an auxiliary roller 23 for changing the direction of travel of the band-shaped flexible substrate 1 by 90 degrees and feeding the same to the film forming section 40.

The film forming section 40 includes a plurality of film forming chambers 42a to 42m arranged linearly for laminating thin films on the surface of the band-shaped flexible substrate 1 in sequence. Pairs of grip rollers 44a to 44m, which pinch the band-shaped flexible substrate 1, are provided on the upstream side of respective substrate entrances of the respective film forming chambers 42a to 42m. As shown in FIG. 2, the pairs of grip rollers 44a/44a′ to 44m/44m′ are arranged along an upper edge portion and a lower edge portion of the band-shaped flexible substrate 1 relative to the vertical direction. The pairs of upper grip rollers 44a to 44m are configured so that the direction of rotation of the respective rollers is inclined obliquely upwardly with respect to the direction in which the band-shaped flexible substrate 1 is conveyed as described below in detail. The pairs of lower grip rollers 44a′ to 44m′ are configured so that the direction of rotation of the respective rollers is inclined obliquely downwardly with respect to the direction in which the band-shaped flexible substrate 1 is conveyed. The upper and lower grip rollers are configured to tension the band-shaped flexible substrate 1 along the widthwise direction.

FIGS. 1 and 2 shows thirteen film forming chambers 42a to 42m. The number of film forming chambers, however, is not limited to thirteen, but may be any numbers as long as a plurality of film forming chambers are present. A plurality of pairs of grip rollers 46a and 46b in succession are provided at a substantially center position of the plurality of film forming chambers, namely adjacent to the seventh film forming chamber 42g, or between the seventh and eighth film forming chambers 42g, 42h. A plurality of pairs of grip rollers 46c and 46d in succession are also provided outside the last film forming chamber, namely adjacent to the substrate exit of the thirteenth film forming chamber 42m. The pairs of lower grip rollers 46a′ to 46d′ for supporting the lower end of the band-shaped flexible substrate 1 relative to the vertical direction are arranged below the pairs of upper grip rollers 46a to 46d.

The side edge position controller 50 in FIG. 1 includes a meandering detection roller 51 for detecting the position of the side edge of the band-shaped flexible substrate 1 coming out from the film forming section 40 and a side edge position controlling (EPC) roller 52 for preventing the band-shaped flexible substrate 1 from meandering vertically, that is, along the widthwise direction. The meandering detection roller 51 or the meandering detection sensor can be provided in a carrier path of the band-shaped flexible substrate 1 as needed. The EPC roller 52 has a roller width larger than the width of the band-shaped flexible substrate 1. The side edge position controller 50 allows compensation of the error in the vertical position (height of conveyance) of the band-shaped flexible substrate 1. The side edge position controller 50 as described above can be provided between the unwinding drive 20 and the film forming section 40 or between the two film forming chambers 42g and 42h positioned at the center of the film forming section 40. In the illustrated embodiment, the grip rollers 44b to 44m are provided respectively between the adjacent film forming chambers 42a to 42m to restrain the meandering of the band-shaped flexible substrate 1 in the film forming section 40, so that provision of the side edge position controller at positions described above is not necessary.

The winding side drive 60 includes a winding-side film drive roller 63 which rotates for conveying the band-shaped flexible substrate 1 from the film forming section 40 to the winding unit 70, a tensile strength detection roller 62 for controlling the tensile strength of the band-shaped flexible substrate 1 at the winding side drive 60 is driven, and an auxiliary roller 61 for receiving the band-shaped flexible substrate 1 from the side edge position controller 50.

The winding unit 70 includes a winding core 71 for winding the band-shaped flexible substrate 1 formed with the thin-film laminated member into a roll, a tensile strength detection roller 73 for detecting the tensile strength of the band-shaped flexible substrate 1 when being wound, and an auxiliary roller 72.

Subsequently, the structure of the film forming chambers 42a to 42m will be described in detail using the periphery of the film forming chamber 42b as a representative. Since a plurality of thin films having different characteristics are laminated on the surface of the band-shaped flexible substrate 1, the structures of the respective film forming chambers can be different depending on the types of the thin films to be formed. The film forming chamber for forming an amorphous silicon layer by plasma CVD will be described here as an example. The same structure can be employed also for the case of forming other types of thin films, as long as the interior of the film forming chamber is brought into a hermetical state.

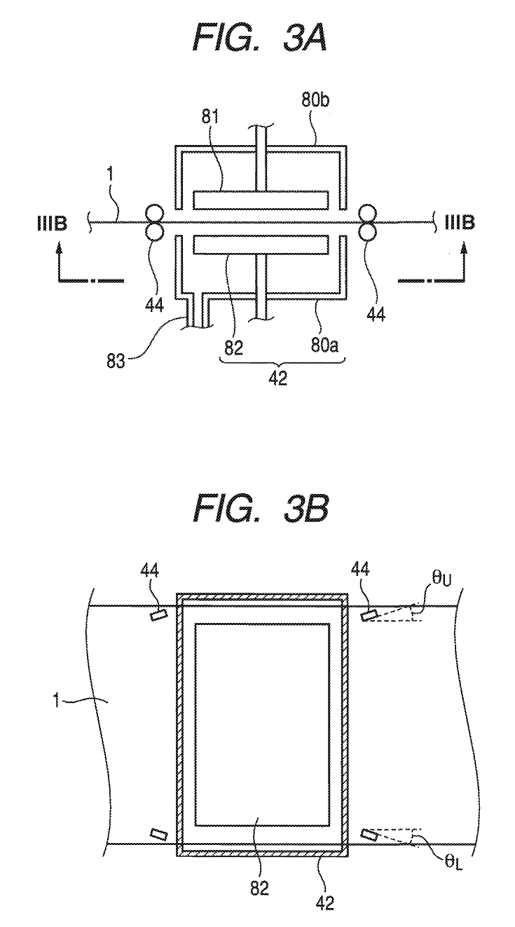

FIG. 3A is a schematic enlarged plan cross section of a periphery of the film forming chamber 42b as a representative of the film forming chambers 42a to 42m shown in FIG. 1. FIG. 3B is a front view taken along the line IIIB-IIIB in FIG. 3A. Referring to FIGS. 3A and 3B, walls 80a and 80b of the film forming chamber having a U-shape in cross section are arranged on opposite sides of the band-shaped flexible substrate 1. When forming a film, the walls 80a and 80b move or displace until the distal ends of the walls come into tight contact with the surfaces of the band-shaped flexible substrate 1. Sealing members (not shown) for bringing the interior of a film forming chamber 42 into a hermetical state are attached to the distal ends of a wall 80.

In an inner space of the film forming chamber 42, a high-voltage electrode 81 and an earth electrode 82 having a substrate heater are installed so as to oppose each other with the band-shaped flexible substrate 1 in between them. The film forming chamber 42 is provided with an exhaust pipe 83 that exhausts the air/gas from the film forming chamber and brings the same into vacuum. The film forming chamber 42 is also provided with an introduction pipe (not shown) for introducing reaction gas such as silane. The introduced reaction gas is decomposed by plasma generated between the high-voltage electrode 81 and the earth electrode 82 and allows formation of a thin film on the band-shaped flexible substrate 1.

The widthwise lengths of the high-voltage electrode 81 and the earth electrode 82 are shorter than the width of the band-shaped flexible substrate 1 so as to leave margins where the thin film is not formed on opposite (upper and lower) ends of the band-shaped flexible substrate 1 as shown in FIG. 3B. Then, the pairs of grip rollers 44b and 44c arranged on the upper side of the band-shaped flexible substrate 1 and the pairs of grip rollers 44b′ and 44c′ arranged on the lower side thereof with the band-shaped flexible substrate 1 interposed between the margins pinch the margins where the thin film is not formed by the pairs of grip rollers 44b, 44c, 44b′ and 44c′, formation of wrinkles on a portion of the band-shaped flexible substrate 1 where the thin film is to be formed or damage of the formed thin film is prevented. Although the pairs of upper grip rollers 44b and 44c can answer the purpose, provision of both the pairs of upper grip rollers 44b and 44c and the pairs of lower grip rollers 44b′ and 44c′ is preferable.

As shown in FIG. 2, the upper pairs of grip rollers 44a to 44m and 46a to 46d are configured with the direction of rotation of the rollers inclined upward with respect to the direction in which the band-shaped flexible substrate 1 is conveyed (along the horizontal direction). In this manner, by forming an angle θU between the direction of rotation of the pairs of upper grip rollers 44a to 44m and 46a to 46d and the direction in which the band-shaped flexible substrate 1 is conveyed, a force to lift the band-shaped flexible substrate 1 upwardly is generated when the band-shaped flexible substrate 1 is conveyed along the horizontal direction, and hence the vertical position of the band-shaped flexible substrate 1 can be maintained with a high degree of accuracy. In particular, the plurality of pairs of grip rollers 46a and 46b provided in succession between the two film forming chambers located in the middle are able to support the mass of the band-shaped flexible substrate 1 and restore the height of the band-shaped flexible substrate 1 being conveyed reliably to the initial height as a reference. The plurality of grip rollers 46c and 46d provided in succession after the last film forming chamber are also able to support the mass of the band-shaped flexible substrate 1 and restore the height of the band-shaped flexible substrate 1 being conveyed reliably as in the case described above. The angle θU can be in a range from 0.1° to 6°. The larger the angle θU is, the larger the force to lift the band-shaped flexible substrate 1 becomes. When the angle θU exceeds 6° or when a static friction of the rollers is exceeded, however, the force to lift the band-shaped flexible substrate 1 is little improved.

As shown in FIG. 2, the pairs of lower grip rollers 44a′ to 44m′ and 46a′ to 46d′ are configured with the direction of rotation thereof inclined downwardly with respect to the direction in which the band-shaped flexible substrate 1 is conveyed (along the horizontal direction). In this manner, by forming an angle θL between the direction of rotation of the pairs of lower grip rollers 44a′ to 44m′ and 46a′ to 46d′ and the direction in which the band-shaped flexible substrate 1 is conveyed, a force to lower the band-shaped flexible substrate 1 downwardly is generated when the band-shaped flexible substrate 1 is conveyed in the horizontal direction, thus further preventing wrinkles on the surface of the band-shaped flexible substrate 1 when the band-shaped flexible substrate 1 is conveyed along the horizontal direction. The angle θL can be in a range from 0.1 to 6°. The angles θU and θL may be the same or may be different.

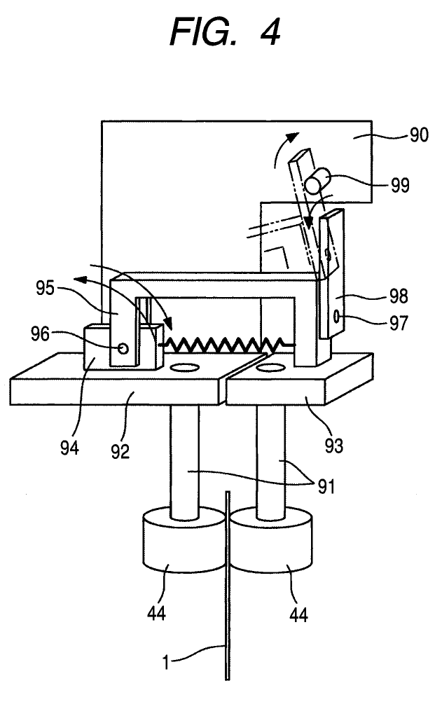

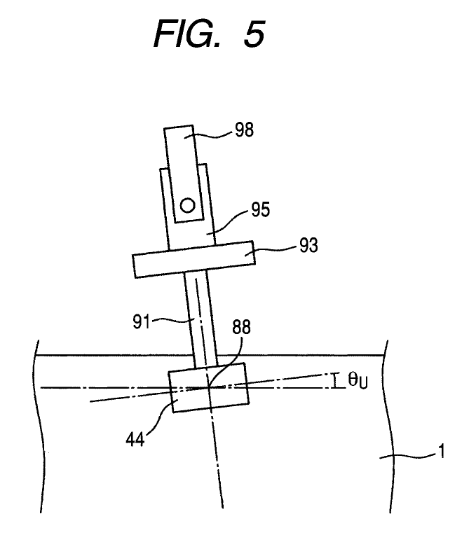

Referring to FIGS. 4 and 5, configurations of the pair of grip rollers 44 and an attached device thereof will be described. The pair of grip rollers 44 are rotatably fixed to the lower end of roller fixing shafts 91. The upper end of one of the roller fixing shafts 91 is fixed to a fixed roller unit 92, and the upper end of the other roller fixing shaft 91 is fixed to a movable roller unit 93.

A rotation supporting member 94 is provided on the upper side of the fixed roller unit 92, and an end of an inverted U-shaped handle 95 is provided on the upper side of the movable roller unit 93. The other end of the handle 95 is rotably supported so that it is rotatable about a hinge or pivot 96 relative to the rotation supporting member 94. The pair of grip rollers 44 are configured to pinch the band-shaped flexible substrate 1 therebetween and to move apart from each other to increase the distance therebetween by rotating the movable roller unit 93 about a hinge 96. The rotation supporting member 94 and the other end of the handle 95 are connected by an extension spring, the length of which is minimized when the band-shaped flexible substrate 1 is pinched between the pair of grip rollers 44.

The strength of the extension spring provides the pressurizing force between the pair of grip rollers 44 with respect to the band-shaped flexible substrate 1. Accordingly, the pressurizing force can be adjustable with different springs.

An end of a lever 98 is attached to the end of the handle 95 so that it is rotatable about a hinge 97. The axis of rotation of the hinge 97 is vertically displaced from the axis of rotation of the hinge 96. The fixed roller unit 92 is fixed to the a fixing plate 90, and a bar 99 extends outwardly from one side of the fixing plate 90. The bar 99 is positioned on a trajectory of the other end of the lever 98 when the handle 95 is rotated about the hinge 96. In other words, the bar 99 is located at a position that hinders the rotation of the handle 95 by coming into contact with the other end of the lever 98. When the lever 98 is rotated about the hinge 97 to prevent the lever 98 from coming into abutment with the bar 99, the handle 95 is allowed to rotate freely.

The grip rollers 44 are installed with the direction of rotation of the roller inclined upward with respect to the direction in which the band-shaped flexible substrate 1 is conveyed as shown in FIG. 5. The angle θU between the direction of rotation of the roller and the direction in which the band-shaped flexible substrate 1 is conveyed can be fixed to a certain angle, or can be configured to be changeable during film formation. When changing the angle θU, the angle is preferably adjusted about center points 88 of the axes of rotation of the grip rollers 44. By adjusting the angle θU with the center points 88 used as fulcrums, formation of the wrinkles on the band-shaped flexible substrate 1 or meandering of the band-shaped flexible substrate 1 can be prevented. In particular, it is preferable to configure the plurality of pairs of grip rollers 46a to 46d arranged in succession on the upper side so that their angles are adjustable. Accordingly, the height of the band-shaped flexible substrate 1 being conveyed can be adjusted to be the initial height as a reference with a high degree of accuracy.

The configurations of the upper grip rollers 44a to 44m and the attached device thereof have been described thus far. The lower grip rollers 44a′ to 44m′ and the attached device thereof can have the same configurations but in a mirror image. The plurality of pairs of grip rollers 46a′ to 46d′ arranged in succession also can have the same configuration but in a mirror image. The surfaces of the grip rollers 44 that come into contact with the band-shaped flexible substrate 1 can be formed of heat-resistant rubber such as silicon rubber or fluorine-contained rubber or synthetic resin such as PTFE or polyimide. A material formed by chrome plating stainless or iron also can achieve the same performance.

The apparatus further has a control device 100 configured to control conveyance and halt (i.e., indexing) of the band-shaped flexible substrate 1 and movement of the walls 80 of the respective film forming chambers 42. In other words, the control device 100 controls the indexing movement of the band-shaped flexible substrate through the film forming chambers to align the horizontal position of the band-shaped flexible substrate at the film forming chambers. The control device 100 can also change the angles θU and θL of the pairs of grip rollers 44a to 44m, 44a′ to 44m′, 46a to 46d and 46a′ to 46d′ according to the extent of meandering of the band-shaped flexible substrate 1 as needed. Broken lines continued to the control device 100 in FIG. 1 represent control signal lines between the control device 100 and the respective units.

The band-shaped flexible substrate 1 passing through the interiors of the plurality of film forming chambers 42a to 42m by the drives 20 and 60 on the unwinding side and the winding side, and the band-shaped flexible substrate 1 is conveyed from the unwinding core 11 to the winding core 71 horizontally. When forming the film, the unwinding-side film drive roller 21 and the winding-side film drive roller 63 stop to halt the band-shaped flexible substrate 1 aligned to the film forming chambers 42a to 42m, and then the walls 80a and 80b of the respective film forming chambers 42a to 42m are moved until they come in tight contact with the band-shaped flexible substrate 1 to bring the interiors of the film forming chambers into a hermetical state. Then, the thin film is formed on the surface of the band-shaped flexible substrate 1 in each film forming chamber.

After having formed the film, the walls 80a and 80b of the film forming chambers are restored to their original position to release the hermetical state. Again, the unwinding-side film drive roller 21 and the winding-side film drive roller 63 are rotated to convey the band-shaped flexible substrate 1 to align the positions of the next film forming chambers. Then, the interiors of the respective film forming chambers are brought into a hermetical state again and the film is formed on the halted band-shaped flexible substrate 1. By repeating the operation to convey the band-shaped flexible substrate 1 and film formation, a thin-film laminated member is formed on the surface of the band-shaped flexible substrate 1.

The band-shaped flexible substrate 1 moves a long distance form the first film forming chamber 42a to the thirteenth film forming chamber 42m. When the band-shaped flexible substrate 1, however, is supported only by the auxiliary roller 23 of the unwinding drive 20 and the meandering detection roller 51 of the side edge position controller 50 positioned on both ends of this section, the band-shaped flexible substrate 1 sags by the gravitational force of the elongation thereof or is meandered in the direction of width (vertically) of the band-shaped flexible substrate 1. In the present embodiment, since the upper grip rollers 44a to 44m pinch the upper side edge of the band-shaped flexible substrate 1 before the respective entrances of the substrate of the first to thirteenth film forming chambers 42a to 42m, the sagging problem can be prevented, and the meandering and wrinkle problems can be prevented even when the band-shaped flexible substrate 1 moves for a long distance from the first film forming chamber 42a to the thirteenth film forming chamber 42m.

In particular, the respective grip rollers 44a to 44m on the vertical upper side of the band-shaped flexible substrate 1 are installed with the direction of rotation of the rollers inclined upwardly with respect to the direction in which the band-shaped flexible substrate 1 is conveyed so as to generate a strong force to lift the band-shaped flexible substrate 1 upwardly. Therefore, even when the band-shaped flexible substrate 1 is conveyed for a distance of 20 m, the vertical meandering of the band-shaped flexible substrate 1 can be restrained to a range of approximately ±2.5 mm.

The film forming device of a stepping roll system that repeats conveyance and halting of the band-shaped flexible substrate has been described thus far. The present apparatus can be adapted not only to the stepping roll system, but also to various types of systems, especially when the band-shaped flexible substrate is conveyed for a long distance in the horizontal direction with the widthwise direction of the band-shaped flexible substrate oriented in the vertical direction.

### EXAMPLES

### Example 1

### Measurement Test of Lifting Force of Band-Shaped Flexible Substrate

Using the grip rollers having the structure shown in FIG. 4 and FIG. 5, a test for measuring the lifting force of the band-shaped flexible substrate 1 was conducted. The grip rollers formed of silicon rubber were used. A Kapton film was used as the band-shaped flexible substrate 1. The pressurizing force of the grip rollers with respect to the band-shaped flexible substrate was changed to three values, namely 4.4 N, 8.9 N, and 16.3 N. The angle θ of the grip rollers in the direction of rotation was changed from 0 to 7° at a 1° increment interval at each pressurizing forces. The lifting force was measured as follows. First, a suspending balance was provided at a position of the band-shaped flexible substrate 1, which is to be pinched by the pair of grip rollers when the band-shaped flexible substrate 1 was not being conveyed and the pair of grip rollers were not in contact with the band-shaped flexible substrate 1, and a relation between the height of the band-shaped flexible substrate 1 and the force required for lifting the band-shaped flexible substrate 1 when the band-shaped flexible substrate 1 was pulled upward were measured in advance. Then, the height of the band-shaped flexible substrate 1 when the height of the band-shaped flexible substrate 1 was stabilized was measured in a state in which the band-shaped flexible substrate 1 was being conveyed and the band-shaped flexible substrate 1 was pinched by the pair of grip rollers. Then, the height of the band-shaped flexible substrate 1 being conveyed was converted into a force required for lifting the band-shaped flexible substrate 1 on the basis of the relation between the height of the band-shaped flexible substrate 1 and the force required for lifting the same which was obtained in advance.

As a result of the test, when the angle θ of the roller in the direction of rotation is 0°, the lifting force was 0 N at any pressurizing forces. When the pressurizing force was as high as 16.3 N, however, the lifting force increased significantly with the increment of the angle θ by 1°, and was increased to about 13 N at an angle θ of 6°. In contrast, when the pressurizing force was as low as 4.4 N, the lifting force was increased with the increment of the angle θ by 1°. Even though the angle θ was increased to 6°, however, the increase of the pressurizing force was only to about 3 N. When the pressurizing force is 8.9 N, the lifting force was increased only to about 6 N even though the angle θ was increased to 6°. The increase of the lifting force was little between the angle θ of 6° and 7° at any pressurizing forces.

### Example 2

### Test of Measurement of Meandering of Band-Shaped Flexible Substrate

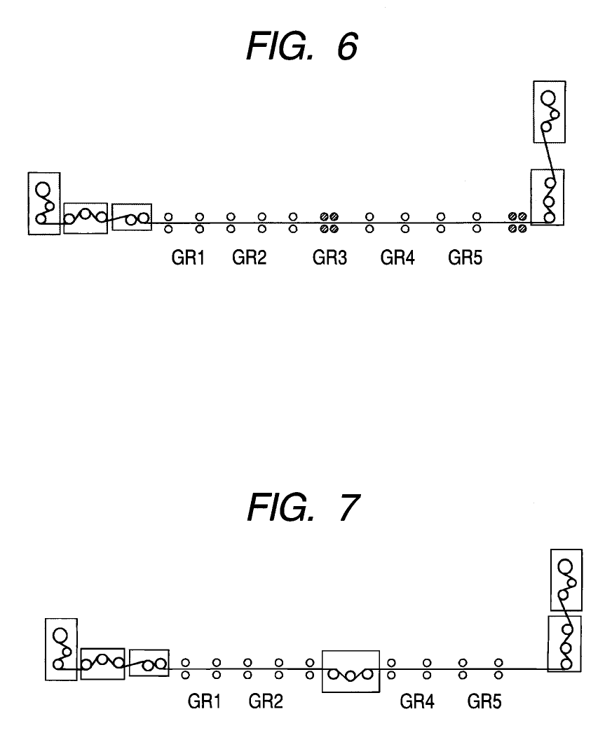

Using experimental devices shown in FIG. 6 and FIG. 7, a test for measuring the vertical meandering of the band-shaped flexible substrate 1 quantitatively was conducted. The basic configuration of the experimental device shown in FIG. 6 is the same as that of the device shown in FIG. 1 and FIG. 2 other than that the side edge position controller is provided on the unwinding side of the film forming section, and that the film forming chamber is not provided. The experimental device shown in FIG. 6 includes nine pairs of the upper and lower grip rollers (both θU and θL at 1°) and only the two pairs of upper grip rollers (θU of 1.5°) in succession at the middle position thereof and the last position respectively. The section in which these pairs of grip rollers were installed, that is, a section between the rollers with the EPC meandering sensor and the feed rollers was set to a length of 20 m. The experimental device shown in FIG. 7 had the same configuration as the experimental device in FIG. 6 other than that the above-described two pairs of upper grip rollers (θU is 1.5°) arranged in succession were not provided at the middle position and the last position, and an intermediate chamber including three EPC rollers was provided at an intermediate position.

### Effects of Material of Band-Shaped Flexible Substrate

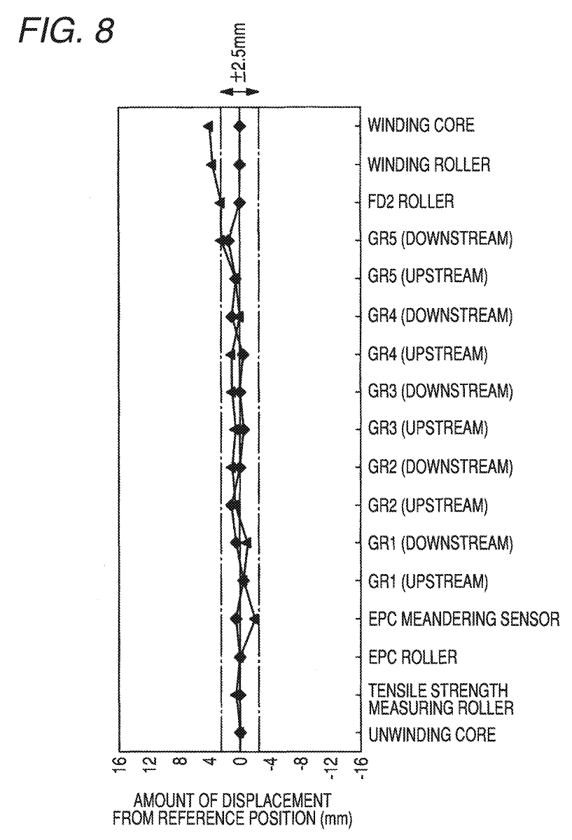

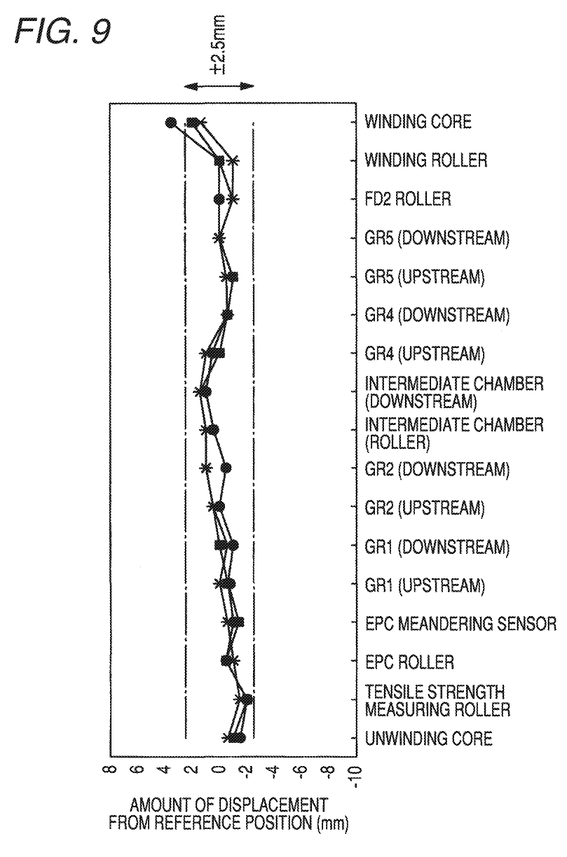

A result of a case in which the Kapton film was used as the band-shaped flexible substrate 1 in the experimental device in FIG. 6 is shown in FIG. 8. As shown in a graph in FIG. 8, the band-shaped flexible substrate 1 meandered little, and the amount of displacement of the band-shaped flexible substrate 1 from the reference position was within the ±2.5 mm. A result of a case in which the Kapton film was used in the experimental device in FIG. 7 is shown in FIG. 9. As a result of the experimental device having the intermediate chamber shown in FIG. 7 as well, the amount of displacement from the reference position was within ±2.5 mm. In this manner, in the case of the experimental device in FIG. 6, which is not provided with the intermediate chamber, meandering of the band-shaped flexible substrate 1 occurred little as in the case of the experimental device shown in FIG. 7, which is provided with the intermediate chamber.

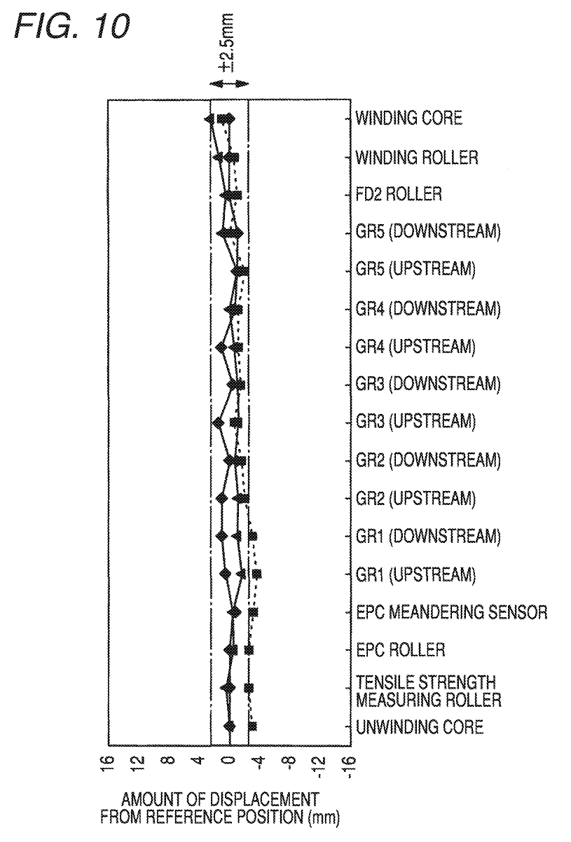

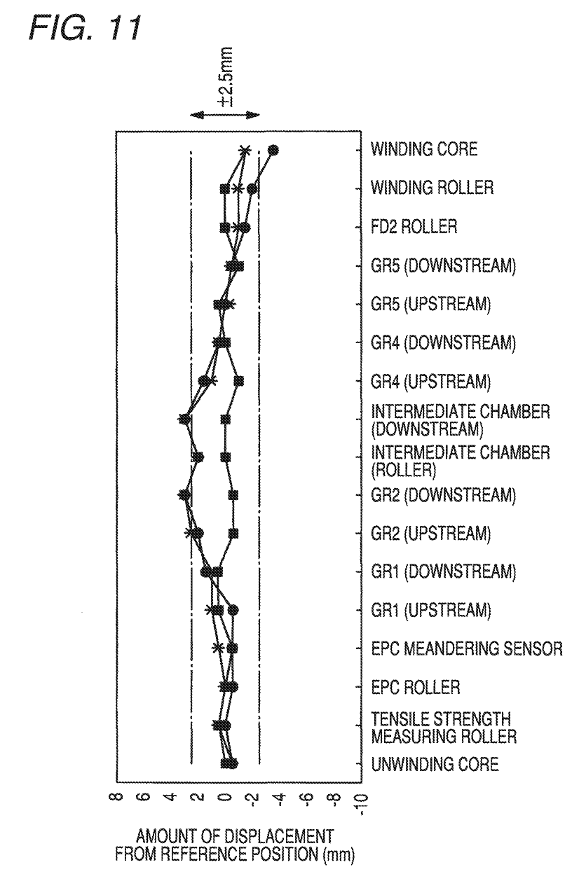

A result of a case in which an amorphous silicon film is used as the band-shaped flexible substrate 1 is shown in FIG. 10. As shown in a graph in FIG. 10, meandering occurred little in the case of the amorphous silicon film, and the amount of displacement of the band-shaped flexible substrate 1 from the reference position was within the ±2.5 mm. A result of a case in which the amorphous silicon film is used in the experimental device in FIG. 7 is shown in FIG. 11. As a result of the experimental device provided with the intermediate chamber in FIG. 7, the amount of displacement of the band-shaped flexible substrate 1 from the reference position was approximately within the ±2.5 mm as well. In this manner, even when the amorphous silicon film is used, in the case of the experimental device in FIG. 6 which is not provided with the intermediate chamber, meandering of the band-shaped flexible substrate 1 occurred little as in the case of the experimental device in FIG. 7, which is provided with the intermediate chamber.

Although the pairs of grip rolls are provided between all the adjacent film forming chambers in the embodiments shown above, a configuration in which the pair of grip rolls are provided only between some of the adjacent film forming chambers as needed is also feasible.

With the arrangement of at least a pair of the grip rollers that pinch the upper edge portion of the band-shaped flexible substrate between the plurality of film forming chambers, even when the band-shaped flexible substrate is conveyed over a long distance through the plurality of film forming chambers, the problems of wrinkles, widthwise meandering, and sagging of the band-shaped flexible substrate can be prevented so that the vertical position of the band-shaped flexible substrate can be maintained with a high degree of accuracy.

By providing a plurality of pairs of upper grip rollers, the weight of the band-shaped flexible substrate can be dispersedly to support the weight and allow the band-shaped flexible substrate to be conveyed more stably.

By obliquely upwardly inclining the direction of rotation of the pairs of upper grip rollers with respect to the direction in which the band-shaped flexible substrate is conveyed, even when the band-shaped flexible substrate is conveyed for a long distance through the plurality of film forming chambers, any sagging portion of the band-shaped flexible substrate is pulled upward when passed through the pairs of upper grip rollers.

By providing at least one pair of lower grip rollers for pinching the lower edge portion of the band-shaped flexible substrate provided between the plurality of film forming chamber, even when the band-shaped flexible substrate is conveyed for a long distance through the plurality of film forming chambers, the band-shaped flexible substrate is supported in the vertical direction by the pairs of upper grip rollers and the pairs of lower grip rollers when the band-shaped flexible substrate, which is subjected to sagging, is conveyed while pinched by the pairs of upper grip rollers and the pairs of lower grip rollers.

By obliquely downwardly inclining the direction of rotation of the pairs of lower grip rollers with respect to the direction in which the band-shaped flexible substrate is conveyed, even when the band-shaped flexible substrate is conveyed for a long distance through the plurality of film forming chambers, when the band-shaped flexible substrate is conveyed in the direction to be conveyed, the band-shaped flexible substrate pinched between the pair of upper grip rollers and the pair of lower grip rollers can be pulled in the vertical direction, both upwardly and downwardly to tension the band-shaped flexible substrate along the widthwise direction.

While the present invention has been particularly shown and described with reference to preferred embodiments, it will be understood by those skilled in the art that the foregoing and other changes in form and details can be made therein without departing from the spirit and scope of the present invention. All modifications and equivalents attainable by one versed in the art from the present disclosure within the scope and spirit of the present invention are to be included as further embodiments of the present invention. The scope of the present invention accordingly is to be defined as set forth in the appended claims.

This application is based on and claims priority to Japanese Patent Applications 2007-202694, 2007-202695, and 2007-202696 all filed on 3 Aug. 2007. The disclosures of the priority applications in their entirety, including the drawings, claims, and the specifications thereof, are incorporated herein by reference.

What is claimed is:

1. An apparatus for manufacturing a thin-film laminated member by laminating a plurality of thin films on the surface of a band-shaped flexible substrate, the apparatus comprising:
a substrate conveying device for conveying the band-shaped flexible substrate horizontally with the band-shaped flexible substrate oriented vertically in the widthwise direction thereof;
a plurality of film forming chambers arranged in succession along the direction in which the band-shaped flexible substrate is conveyed for forming films on the surface of the band-shaped flexible substrate; and
at least a pair of upper grip rollers arranged between the plurality of film forming chambers and configured to pinch an upper edge portion of the band-shaped flexible substrate while the band-shaped substrate is being conveyed.

2. The apparatus according to claim 1, wherein a plurality of pairs of the upper grip rollers are arranged adjacent at least one of the film forming chambers for pinching the upper edge portion of the band-shaped flexible substrate.

3. The apparatus according to claim 1, wherein the direction of rotation of the pairs of the upper grip rollers is inclined obliquely upwardly with respect to the direction in which the band-shaped flexible substrate is conveyed.

4. The apparatus according to claim 2, wherein the direction of rotation of the pairs of the upper grip rollers is inclined obliquely upwardly with respect to the direction in which the band-shaped flexible substrate is conveyed.

5. The apparatus according to claim 1, further including at least one pair of lower grip rollers for pinching the lower edge portion of the band-shaped flexible substrate between the plurality of film forming chambers while the band-shaped flexible substrate is being conveyed.

6. The apparatus according to claim 2, further including at least one pair of lower grip rollers for pinching the lower edge portion of the band-shaped flexible substrate between the plurality of film forming chambers while the band-shaped flexible substrate is being conveyed.

7. The apparatus according to claim 3, further including at least one pair of lower grip rollers for pinching the lower edge portion of the band-shaped flexible substrate between the plurality of film forming chambers while the band-shaped flexible substrate is being conveyed.

8. The apparatus according to claim 4, further including at least one pair of lower grip rollers for pinching the lower edge portion of the band-shaped flexible substrate between the plurality of film forming chambers while the band-shaped flexible substrate is being conveyed.

9. The apparatus according to claim 5, wherein the direction of rotation of the pairs of lower grip rollers is inclined obliquely downwardly with respect to the direction in which the band-shaped flexible substrate is conveyed.

10. The apparatus according to claim 6, wherein the direction of rotation of the pairs of lower grip rollers is inclined obliquely downwardly with respect to the direction in which the band-shaped flexible substrate is conveyed.

11. The apparatus according to claim 7, wherein the direction of rotation of the pairs of lower grip rollers is inclined obliquely downwardly with respect to the direction in which the band-shaped flexible substrate is conveyed.

12. The apparatus according to claim 8, wherein the direction of rotation of the pairs of lower grip rollers is inclined obliquely downwardly with respect to the direction in which the band-shaped flexible substrate is conveyed.

13. A method of conveying a band-shaped flexible substrate in an apparatus for manufacturing a thin-film laminated member by laminating a plurality of thin films on the surface of the band-shaped flexible substrate in a plurality of film forming chambers arranged in succession along the direction in which the band-shaped flexible substrate is conveyed, the method comprising the steps of:
conveying the band-shaped flexible substrate horizontally with the band-shaped flexible substrate oriented vertically in the widthwise direction thereof; and
pinch an upper edge portion of the band-shaped flexible substrate with at least a pair of upper grip rollers arranged between the plurality of film forming chambers while the band-shaped flexible substrate is being conveyed.

14. The method according to claim 13, wherein a plurality of pairs of the upper grip rollers are arranged adjacent to at least one of the film forming chambers for pinching the upper edge portion of the band-shaped flexible substrate.

15. The method according to claim 13, wherein the direction of rotation of the pairs of upper grip rollers is inclined obliquely upwardly with respect to the direction in which the band-shaped flexible substrate is conveyed.

16. The method according to claim 14, wherein the direction of rotation of the pairs of upper grip rollers is inclined obliquely upwardly with respect to the direction in which the band-shaped flexible substrate is conveyed.

17. The method according to claim 13, further including the step of pinching the lower edge portion of the band-shaped flexible substrate with at least one pair of lower grip rollers provided between the plurality of film forming chambers while the band-shaped flexible substrate is being conveyed.

18. The method according to claim 16, wherein the direction of rotation of the pairs of lower grip rollers is inclined obliquely downwardly with respect to the direction in which the band-shaped flexible substrate is conveyed.

19. The method according to claim 17, wherein the direction of rotation of the pairs of lower grip rollers is inclined obliquely downwardly with respect to the direction in which the band-shaped flexible substrate is conveyed.

20. The method according to claim 18, wherein the direction of rotation of the pairs of lower grip rollers is inclined obliquely downwardly with respect to the direction in which the band-shaped flexible substrate is conveyed.
